(19) United States
(12) Patent Application Publication
(10) Pub. No.: US 2016/0219690 A1
(43) Pub. Date: Jul. 28, 2016

(54) WIRING BOARD

(71) Applicant: KYOCERA Circuit Solutions, Inc., Kyoto (JP)

(72) Inventor: Yasuki ITOH, Omihachiman-shi (JP)

(73) Assignee: KYOCERA Circuit Solutions, Inc., Kyoto (JP)

(21) Appl. No.: 15/001,383

(22) Filed: Jan. 20, 2016

(30) Foreign Application Priority Data
Jan. 26, 2015 (JP) 2015-011948

(51) Int. Cl. H05K 1/02

(52) U.S. Cl. CPC H05K 1/0213

(57) ABSTRACT

A wiring board of the present invention includes a core substrate, insulating layers laminated on upper and lower surfaces of the core substrate, and a conductor layer deposited on the upper and lower surfaces of the core substrate and a surface of each of the insulating layers, in such a manner as to make a difference in area occupation ratio between the upper and lower surfaces of the core substrate. A thickness of a conductor that has a large area occupation ratio is smaller than a thickness of a conductor that has a small area occupation ratio between the conductor layers deposited on the upper and lower surfaces of the core substrate, and between the conductor layers deposited on the surface of each of the insulating layers laminated at an identical level on upper and lower surface sides with the core substrate as a center.

### BACKGROUND OF THE INVENTION

1. Field of the Invention

The present invention relates to a wiring board for mounting a semiconductor element.

2. Description of the Related Art

FIG. 3 shows a conventional wiring board B for mounting a semiconductor element S′. The wiring board B includes an insulating substrate 20, a conductor layer 23, and a solder resist layer 24.

The insulating substrate 20 is obtained by laminating insulating layers 26a and 26b on an upper surface of a core substrate 25, and insulating layers 26c and 26d on a lower surface of the core substrate 25. The insulating substrate 20 has a mounting portion X′ for mounting the semiconductor element S′ at a central portion. The core substrate 25 is formed of an electrical insulating material obtained by, for example, impregnating a glass cloth with epoxy resin, bismaleimide triazine resin, or the like, followed by curing.

The core substrate 25 has a plurality of through holes 27. The core substrate 25 has a coefficient of thermal expansion of approximately 8 ppm/° C. A conductor layer 23 is deposited on the upper and lower surfaces of the core substrate 25 and in the through holes 27. The insulating layers 26a to 26d are formed of an electrical insulating resin, such as epoxy resin and bismaleimide triazine resin.

Each of the insulating layers 26a to 26d has a plurality of via holes 28. The insulating layers 26a to 26d have a coefficient of thermal expansion of approximately 40 ppm/° C. The conductor layer 23 is deposited on a surface of each of the insulating layers 26a to 26d and in the via holes 28. The conductor layer 23 is formed of, for example, copper. The conductor layer 23 has a coefficient of thermal expansion of approximately 17 ppm/° C.

The mounting portion X′ has a plurality of semiconductor element connection pads 21. The semiconductor element connection pads 21 are formed of the conductor layer 23. An electrode T′ of the semiconductor element S′ is connected to these semiconductor element connection pads 21 through a solder. The connection between the electrode T′ of the semiconductor elements S′ and the semiconductor element connection pads 21 is made using, for example, well-known reflow processing. The insulating layer 26d has a plurality of external connection pads 22. The external connection pads 22 are formed of the conductor layer 23. The external connection pads 22 are connected to a conductor layer of an external electric circuit board through a solder.

The conductor layer 23 includes conductor layers for signal, grounding, and a power supply. The conductor layer 23 for the signal has a plurality of band-shaped wiring patterns. These band-shaped wiring patterns are spaced apart a predetermined distance from one another on a surface of the insulating layer 26b on an upper surface side and extend from below the mounting portion X′ toward an outer peripheral side of the insulating layer 26b. The conductor layer 23 for grounding or the power supply has a plurality of large-area plane conductors. These plane conductors are formed on upper and lower surfaces of the core substrate 25 and a surface of each of the insulating layers 26b to 26d. The plane conductors formed on the insulating layer 26b on the upper surface side are spaced apart a predetermined distance from one another along the circumference of the conductor layer 23 for the signal. Other plane conductors are formed on approximately entirely over the upper and lower surfaces of the core substrate 25 and the surface of each of the insulating layers 26c and 26d on the lower surface side.

The solder resist layer 24 is formed on the surface of the outermost insulating layers 26a and 26d. The solder resist layer 24 formed on the surface of the insulating layer 26a on the upper surface side has openings 24a to expose a central portion of each of the semiconductor element connection pads 21. The solder resist layer 24 formed on the surface of the insulating layer 26d on the lower surface side has openings 24b to expose a central portion of each of the external connection pads 22. This conventional wiring board is described in, for example, Japanese Unexamined Patent Publication No. 2012-99692.

Meanwhile, the conventional wiring board B has the conductor layer 23 for the signal, grounding, and the power supply as described above. Therefore, an area occupation ratio of the conductor layer 23 in the layer having the plane conductors formed over approximately the entire surface thereof is larger than an area occupation ratio of the conductor layer 23 in the layer having a plurality of the band-shaped conductor patterns spaced apart the predetermined distance from one another.

As described above, the coefficient of thermal expansion of the conductor layer 23 is different from either the coefficient of thermal expansion of the core substrate 25 or the coefficient of the thermal expansion of the insulating layers 26a to 26d. Therefore, a difference in thermal expansion and contraction behavior between the layer having the large area occupation ratio of the conductor and the layer having the small area occupation ratio of the conductor becomes large, for example, during heating and cooling in the foregoing reflow processing. Consequently, warping occurs on the wiring board B, and a distance between the electrode T′ of the semiconductor element S′ and the semiconductor element connection pads 21 varies widely. This leads to the problem that it is difficult to surely weld the solder to the electrode T′ and the semiconductor element connection pads 21, thus failing to achieve a stable operation of the semiconductor element.

### SUMMARY OF THE INVENTION

An embodiment of the present invention aims at reducing warping of a wiring board by minimizing a difference in thermal expansion and contraction behavior between conductor layers on upper and lower surfaces of a core substrate, and between conductor layers formed at an identical level on upper and lower surface sides with the core substrate as a center. The embodiment thereby provides a wiring board having a semiconductor element surely mounted thereon to ensure a stable operation of the semiconductor element.

The wiring board according to the embodiment of the present invention includes the core substrate, the insulating layers laminated with an identical number of layers on the upper and lower surfaces of the core substrate, and the conductor layer deposited on the upper and lower surfaces of the core substrate and a surface of each of the insulating layers respectively laminated on the upper and lower surfaces of the core substrate, in such a manner as to make a difference in area occupation ratio between the upper and lower surfaces of the core substrate. A thickness of a conductor that has a large area occupation ratio is smaller than a thickness of a conductor that has a small area occupation ratio between the conductor layers deposited on the upper and lower surfaces of the core substrate, and between the conductor layers deposited on the surface of each of the insulating layers laminated at the identical level on the upper and lower surface sides with the core substrate as the center.

According to the wiring board of the embodiment of the present invention, the thickness of the conductor that has the large area occupation ratio is formed to be smaller than the thickness of the conductor that has the small area occupation ratio between the conductor layers formed on the upper and lower surfaces of the core substrate, and between the conductor layers formed at the identical level on the upper and lower surface sides with the core substrate as the center. Thus, the thermal expansion and contraction behavior difference is reducing by minimizing a volume difference between the conductor layers, thereby minimizing the warping generated on the wiring board. During mounting of the semiconductor element, variations in the distance between the electrode of the semiconductor element and the semiconductor element connection pads can be reduced to ensure a strong connection therebetween with the solder. It is consequently possible to provide the wiring board capable of stably operating the semiconductor element.

### BRIEF DESCRIPTION OF THE DRAWINGS

FIG. 1 is a schematic sectional view showing a wiring board according to one embodiment of the present invention;

FIG. 2 is a principal part enlarged view of the wiring board according to the one embodiment of the present invention; and

FIG. 3 is a schematic sectional view showing a conventional wiring board.

### DESCRIPTION OF THE EMBODIMENTS

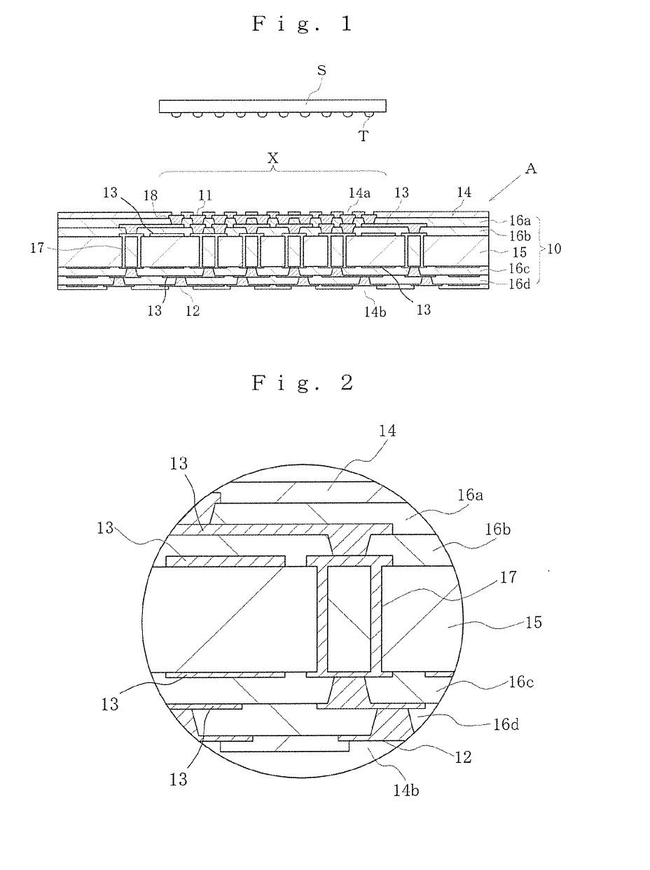

A wiring board according to the one embodiment is described with reference to FIG. 1. The wiring board A shown in FIG. 1 includes an insulating substrate 10, a conductor layer 13, and a solder resist layer 14.

The insulating substrate 10 is obtained by laminating insulating layers 16a and 16b on an upper surface of a core substrate 15, and insulating layers 16c and 16d on a lower surface of the core substrate 15. The insulating substrate 10 has a mounting portion X for mounting a semiconductor element S at a central portion on an upper surface thereof. The core substrate 15 is formed of an electrical insulating material obtained by, for example, impregnating a glass cloth with epoxy resin, bismaleimide triazine resin, or the like, followed by curing.

The core substrate 15 has a plurality of through holes 17. The conductor layer 13 is deposited on upper and lower surfaces of the core substrate 15 and in the through holes 17. The through holes 17 are formed by, for example, drilling, laser processing, or blast processing. The through holes 17 preferably have a diameter of approximately 100 to 300 μm. The core substrate 15 usually has a coefficient of thermal expansion of 3 to 15 ppm/° C., preferably approximately 8 ppm/° C.

The insulating layers 16a to 16d are formed of a thermosetting resin, such as epoxy resin and polyimide resin. An inorganic insulation filler, such as silicon oxide powder, may be dispersed in the thermosetting resin. The insulating layers 16a to 16d usually have a coefficient of thermal expansion of 39 to 46 ppm/° C., preferably approximately 40 ppm/° C.

Each of the insulating layers 16a to 16d has a plurality of via holes 18. The conductor layer 13 is deposited on a surface of each of the insulating layers 16a to 16d and to in the via holes 18. The via holes 18 are formed by, for example, laser processing. The via holes 18 preferably have a diameter of approximately 30 to 100 μm.

The conductor layer 13 is formed of a highly conductive metal such as copper. The conductor layer 13 is formed by semi-additive method using well-known subtractive method, electroplating method, or the like. The conductor layer 13 usually has a coefficient of thermal expansion of 16.5 to 17.7 ppm/° C., preferably approximately 17 ppm/° C.

The mounting portion X has a plurality of semiconductor element connection pads 11. These semiconductor element connection pads 11 are formed of the conductor layer 13. An electrode T of the semiconductor element S is connected to these semiconductor element connection pads 11 through a solder. The connection between the electrode T of the semiconductor element S and the semiconductor element connection pads 11 is made using, for example, well-known reflow processing.

The lowermost insulting layer 16d has a plurality of external connection pads 12. These external connection pads 12 are formed of the conductor layer 13. These external connection pads 12 are connected to wiring on the external electric circuit board through a solder.

The conductor layer 13 includes conductor layers for a signal, grounding, and a power supply. The conductor layer 13 for the signal has a plurality of band-shaped wiring patterns. These band-shaped wiring patterns are, for example, spaced apart a predetermined distance from one another on a surface of the insulating layer 16b on the upper surface side and extend from below the mounting portion X toward an outer peripheral side of the insulating layer 16b.

The conductor layer 13 for grounding or the power supply has a plurality of large-area plane conductors. These plane conductors are formed on the upper and lower surfaces of the core substrate 15 and the surface of each of the insulating layers 16b to 16d. The plane conductors formed on the insulating layer 16b on the upper surface side are spaced apart a predetermined distance from one another along the circumference of the conductor layer 13 for the signal. Other plane conductors are formed on approximately entirely over the upper and lower surfaces of the core substrate 15 and the surface of each of the insulating layers 16c and 16d on the lower surface side.

Therefore, an area occupation ratio of the conductor layer 13 in the layer having the plane conductors formed over approximately the entire surface thereof is larger than an area occupation ratio of the conductor layer 13 in the layer having a plurality of the band-shaped conductor patterns spaced apart the predetermined distance from one another.

The solder resist layer 14 is formed on the surface of each of the outermost insulating layers 16a and 16d. The solder resist layer 14 formed on the surface of the insulating layer 16a on the upper surface side has openings 14a to expose a central portion of each of the semiconductor element connection pads 11. The solder resist layer 14 formed on the surface of the insulating layer 16d on the lower surface side has openings 14b to expose a central portion of each of the external connection pads 12.

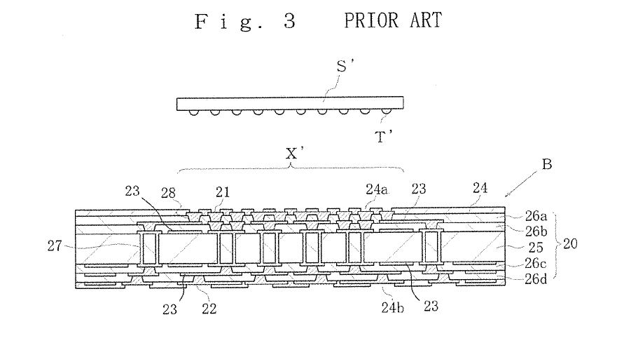

Meanwhile, in the wiring board A shown in FIG. 1, there is a difference in the thickness of the conductor layer 13 between the conductor layers 13 formed on the upper and lower surfaces of the core substrate 15, and between the conductor layers 13 formed at the identical level on the upper and lower surface sides with the core substrate 15 as the center, as shown in FIG. 2. That is, the thickness of the conductor having the large area occupation ratio of the conductor layer is formed to be smaller than the thickness of the conductor having the small area occupation ratio of the conductor layer. The thickness of the conductor having the larger area occupation ratio of the conductor layer is preferably approximately 3 to 5 μm smaller than the thickness of the conductor having the small area occupation ratio of the conductor layer.

Thus, the thermal expansion and contraction behavior difference is reduced by decreasing a volume difference between the conductor layers 13, thereby minimizing the warping generated on the wiring board A. During mounting of the semiconductor element S, variations in the distance between the electrode T of the semiconductor element S and the semiconductor element connection pads 11 can be reduced to ensure a strong connection therebetween with the solder. It is consequently possible to provide the wiring board A capable of stably operating the semiconductor element S.

No particular limitation is imposed on the method of making a difference in the conductor thickness between the conductor layers 13 formed at the identical level. For example, an employable method includes forming the conductor layers 13 formed at the identical level, and then thinning only one of the conductor layers 13 by etching.

When forming the conductor layers 13 by electroplating method, the following method is employable. Firstly, a first anode plate and a second anode plate are disposed oppositely to each other in a bath. Subsequently, a wiring board in the middle of production is disposed between the first and second anode plates so that a plating deposited surface faces the first and second anode plates. Then, plating for the conductor layer 13 is deposited in a state in which a current value of the anode plate facing the deposited surface on the side which needs a large conductor thickness is larger than a current value of the anode plate facing the deposited surface on the side which needs a small conductor thickness.

The present invention is not limited to the one embodiment as described above, and various modifications are possible as long as they are within the scope of the claims. For example, the wiring board A according to the one embodiment as described above has the two insulating layers 16a and 16b laminated on the upper surface of the core substrate 15 and two insulating layers 16c and 16d laminated on the lower surface of the core substrate 15. The number of the insulating layers to be laminated thereon may be one or three or more.

What is claimed is:

1. A wiring board comprising:
a core substrate;
insulating layers laminated with an identical number of layers on upper and lower surfaces of the core substrate; and
a conductor layer deposited on the upper and lower surfaces of the core substrate and a surface of each of the insulating layers respectively laminated on the upper and lower surfaces of the core substrate, in such a manner as to make a difference in area occupation ratio between the upper and lower surfaces of the core substrate,
wherein a thickness of a conductor that has a large area occupation ratio is smaller than a thickness of a conductor that has a small area occupation ratio between the conductor layers deposited on the upper and lower surfaces of the core substrate, and between the conductor layers deposited on the surface of each of the insulating layers laminated at an identical level on upper and lower surface sides with the core substrate as a center.

2. The wiring board according to claim 1, wherein the insulating layers are laminated in a two-layer structure on upper and lower surfaces of the core substrate.

3. The wiring board according to claim 1, wherein the thickness of the conductor having the large area occupation ratio is 3 to 5 μm smaller than the thickness of the conductor having the small area occupation ratio.
